(19) United States
(12) Patent Application Publication
(10) Pub. No.: US 2005/0268963 A1
(43) Pub. Date: Dec. 8, 2005

(54) Process for manufacturing photovoltaic cells

(76) Inventors: David Jordan, Mudgee (AU); John H. Wohlgemuth, Ijamsville, MD (US)

Correspondence Address: CAROL WILSON;BP AMERICA INC., MAIL CODE 5 EAST, 4101 WINFIELD ROAD, WARRENVILLE, IL, 60555, US

(21) Appl. No.: 11/064,337

(22) Filed: Feb. 23, 2005

Related U.S. Application Data
(60) Provisional application No. 60/547,123, filed on Feb. 24, 2004.

(51) Int. Cl. H01L 31/00; H01L 21/00

(52) U.S. Cl. 136/256; 438/71; 257/466

(57) ABSTRACT

A process for making a photovoltaic cell using a semiconductor wafer doped with a first dopant, the wafer comprising a front surface and a back surface, the process comprising the steps of forming a first layer on the front surface of the wafer, the first layer comprising a second dopant of a conductivity type opposite the first dopant; depositing a surface coating on the front surface over the first layer; forming grooves in the front surface after depositing the surface coating thereon; adding a second dopant to the grooves; depositing a doping material on the back surface; treating the wafer having the doping material deposited thereon to form a back surface field, masking at least a portion of the back surface of the wafer after the treating; and adding a conductive material to the grooves to form an electrical contact.

This invention claims the benefit of U.S. Provisional Patent Application No. 60/547,123 filed on Feb. 24, 2004.

### BACKGROUND OF THE INVENTION

This invention relates to a process for manufacturing photovoltaic cells. More particularly, this invention relates to a process for manufacturing photovoltaic cells that are highly efficient in converting light energy, and particularly solar energy, to electrical energy that uses a mask on the back surface of the cell during a plating step in the formation of the electrical contacts for the photovoltaic cell. This invention is also a photovoltaic cell that can be made by such process.

One of the most important features of a photovoltaic cell is its efficiency in converting light energy from the sun into electrical energy. Another important feature is the ability to manufacture such cell in a safe manner applicable to large-scale manufacturing processes. Thus, the art is continuously striving to not only improve the efficiency of photovoltaic cells in converting light energy into electrical energy, but also to manufacture them using safe, environmentally compatible, large-scale manufacturing processes.

Although photovoltaic cells can be fabricated from a variety of semiconductor materials, silicon is generally used because it is readily available at reasonable cost and because it has the proper balance of electrical, physical and chemical properties for use in fabricating photovoltaic cells. In a typical procedure for the manufacture of photovoltaic cells using silicon as the selected semiconductor material, the silicon is doped with a dopant of either positive or negative conductivity type, formed into either ingots of monocrystalline silicon, or cast into blocks or “bricks” of what the art refers to as multicrystalline silicon, and these ingots or blocks are cut into thin substrates, also referred to as wafers, by various slicing or sawing methods known in the art. However, these are not the only methods used to obtain suitable semiconductor wafers for the manufacture of photovoltaic cells.

By convention, positive conductivity type is commonly designated as “p” or “p-type” and negative conductivity type is designated as “n” or “n-type”. However, where applicable, “p” and “n” are used herein only to indicate opposing conductivity types.

The surface of the wafer intended to face incident light when the wafer is formed into a photovoltaic cell is referred to herein as the front face or front surface, and the surface of the wafer opposite the front face is referred to herein as the back face or back surface.

A p-doped wafer is exposed to a suitable n-dopant to form an emitter layer and a p-n junction. In one method, the n-doped layer or emitter layer is formed by first depositing the n-dopant onto the surface of the p-doped wafer using techniques commonly employed in the art such as chemical or physical deposition and, after such deposition, the n-dopant is driven into the surface of the silicon wafer to further diffuse the n-dopant into the wafer surface. This “drive-in” step is commonly accomplished by exposing the wafer to heat. A p-n junction is thereby formed at the boundary region between the n-doped layer and the p-doped silicon wafer substrate. In another method, the exposure to the n-dopant and the heating to drive in the dopant can be accomplished at the same time. The wafer surface, prior to the n-doping to form the emitter layer, can be textured.

In order to utilize the electrical potential generated by exposing the p-n junction to light energy, the photovoltaic cell is typically provided with a conductive front electrical contact and a conductive back electrical contact. Such contacts are typically made of one or more highly conducting metals and are, therefore, typically opaque. Since the front contact is on the side of the photovoltaic cell facing the sun or other source of light energy, it is generally desirable for the front contact to take up the least amount of area of the front surface of the cell as possible yet still capture and conduct the charge carriers generated by the incident light interacting with the cell.

A number of methods have been developed in the art for applying front contacts to monocrystalline and multicrystalline silicon wafers. A typical procedure is to screen print strips of conductive material using a paste and then firing the paste at an elevated temperature to form conductive contacts. Another method is to form a buried contact. A buried front contact is made by scribing or cutting a pattern of scribes or grooves into the front surface of the wafer in an open grid pattern and thereafter filling the grooves with a conducting material such as a highly conducting metal. A laser can be used to form the grooves for the buried grid contact. Methods for forming buried contacts are described in, for example, U.S. Pat. No. 4,726,850, to Wenham et al., which is incorporated herein by reference in its entirety.

One method for making photovoltaic cells having buried front contacts follows a processing sequence as follows. The n-layer is created in a p-type monocrystalline or multicrystalline silicon wafer by diffusing phosphorus into the p-type wafer thereby forming a p-n junction. A layer of a dielectric material, for example, a layer of silicon nitride, is applied to the surface of the wafer having the p-n junction. This dielectric material serves as both an anti-reflective coating, and, as described below, a mask. This will, ultimately, be the light receiving side of the cell. Using a laser, narrow and deep grooves are cut through the dielectric layer and into the silicon wafer in a pattern that will form the front buried contact. The grooves are etched with a chemical solution, such as sodium hydroxide, to further form the grooves and remove laser induced damage. Additional phosphorous is diffused into the walls of the grooves. The dielectric layer serves as a mask to limit the doping to the grooves. Such doping of the surfaces within the grooves completes the formation of the emitter layer and p-n junction. Prior to adding the front and back contacts, a back surface field is preferably added to the wafer by heavily p-doping the back surface of the wafer. Such p-doping can be achieved by applying aluminum or boron to the back surface of the wafer, typically by one or more sputtering or metal evaporation techniques known to those of skill in the art followed by a high temperature sintering step. The complete back surface and grooves in the front of the cell are filled with a conductor, for example, one or more of silver, nickel, or copper, by one or more methods such as electrolytic or electroless plating. The dielectric layer again serves as a mask so that the plating on the front side of the wafer is limited to the grooves. An edge isolation step separates any electrical connections between the front and back of the cell.

A process for producing a photovoltaic cell having a buried front contact using, inter alia, processing steps in the sequence of silicon nitride coating of the front surface, laser grooving, sodium hydroxide etch, diffusion of grooves, applying back contact and firing, applying front contact and firing, and edge isolation, is disclosed in U.S. Pat. No. 4,726,850 (disclosed as “Sequence B” therein), as being one which may yield a higher efficiency photovoltaic cell.

In a variation of the process just described, aluminum is used to form the back surface field and is applied to the wafer by screen printing an aluminum-containing paste. After the wafer is subjected to the high temperature sintering step, residual aluminum on the back surface is removed or “stripped off” the wafer. Such stripping has been accomplished using hydrochloric acid to react with and remove the aluminum. After the aluminum is removed, the back contact can be applied, for example by electrolytic or electroless plating. Such process of screen printing the aluminum for the back surface field, high temperature firing, stripping using hydrochloric acid as an etchant to remove the excess aluminum, and addition of the back contact has been shown to form an efficient photovoltaic cell. Such a process is described in the paper by Jooss, Fischer, Fath, Roberts and Bruton titled “Processing and Characterization of Large Area Buried Contact Solar Cells on Multicrystalline Silicon with a Record Efficiency of 17.5%”, from the proceedings of the conference “PV in Europe—from PV Technology to Energy Solutions”, 7-11 Oct. 2002, Rome, Italy, pages 230-235, which is incorporated by reference herein in its entirety. While such a processing sequence results in an efficient, buried contact photovoltaic cell, the use of hydrochloric acid or other similar etchant to remove the aluminum is not suitable for large-scale commercial production because of the formation of a large amount of spent hydrochloric acid and the slurry of residual aluminum which must be treated in a safe way, and disposed of in an environmentally safe manner. Additionally, a process where aluminum is applied, etched away and then replaced with a plated metal is an expensive process since it requires the use of a metal layer that is later discarded.

Consequently, the art needs a process for the manufacture of a photovoltaic cell that can obtain the benefits of screen printing an aluminum-containing paste to the back surface of the wafer followed by firing, yet avoid the use of hydrochloric acid or other aggressive etchant and the formation of the slurry of spent hydrochloric acid and aluminum. Additionally, the art needs a process that can be used for making highly efficient photovoltaic cells using multicrystalline silicon wafers, rather than monocrystalline silicon wafers. Multicrystalline silicon wafers are preferred because they are more cheaply manufactured than wafers made from ingots of monocrystalline silicon.

The present invention provides for such process and the present invention provides for new photovoltaic cells that can be made by such processes.

### SUMMARY OF THE INVENTION

This invention is a process for making a photovoltaic cell using a semiconductor wafer doped with a first dopant, the wafer comprising a front surface and a back surface, the process comprising the steps of (a) forming a first layer on the front surface of the wafer, the first layer comprising a second dopant of a conductivity type opposite the first dopant; (b) depositing a surface coating on the front surface over the first layer; (c) forming grooves in the front surface after depositing the surface coating thereon; (d) adding a second dopant to the grooves; (e) depositing a doping material on the back surface; (f) treating the wafer having the doping material deposited thereon to form a back surface field (BSF); (g) masking at least a portion of the back surface of the wafer after the treating; and (h) adding a conductive material to the grooves to form an electrical contact. Preferably, the mask covers the entire back surface except for areas on the back surface where electrical bus bar pads are located. The bus bar pads are used to solder wires or other electrical conduits to the back of the finished photovoltaic cell.

Thus, in the process of manufacturing a photovoltaic cell, the process of this invention comprises the process steps of masking at least part of the back surface of the wafer after applying a doping material for a back surface field, and, in a later process step, depositing a conductive metal layer, such as, for example one comprising one or more of nickel, copper and silver, to form a front contact.

This invention is also a new photovoltaic cell comprising a masking layer over a screen printed back contact and a back surface field.

### BRIEF DESCRIPTION OF THE DRAWING

FIG. 1 shows a schematic cross-section view of part of a photovoltaic cell made in accordance with an embodiment of this invention.

FIG. 2 shows a schematic, cross-section view of part of a masked silicon wafer made in accordance with an embodiment of this invention.

### DETAILED DESCRIPTION OF THE INVENTION

The invention will now be described using as an example an embodiment of the invention whereby a photovoltaic cell is made using a p-doped silicon wafer. However, it is to be understood that the invention is not limited thereby and is, for example, applicable to other semiconductor materials such as an n-doped silicon wafer.

A silicon wafer useful in the process of this invention for preparing photovoltaic cells is typically in the form of a thin, flat shape. The silicon may comprise one or more additional materials, such as one or more semiconductor materials, for example germanium, if desired. Although boron is widely used as the first, p-type dopant, other p-type dopants, for example gallium or indium, will also suffice. Boron is the preferred p-type dopant. Combinations of such dopants are also suitable. Thus, the first dopant can comprise, for example, one or more of boron, gallium or indium, and preferably it comprises boron. Suitable wafers are typically obtained by slicing or sawing p-doped silicon ingots, such as ingots of monocrystalline silicon, to form monocrystalline wafers, such as the so-called Czochralski (Cz) silicon wafers. Suitable wafers can also be made by slicing or sawing blocks of cast, p-doped multicrystalline silicon. Silicon wafers can also be pulled straight from molten silicon using processes such as Edge-defined Film-fed Growth technology (EFG) or similar techniques. Wafers made by slicing or sawing blocks or “bricks” of multicrystalline silicon are the preferred wafers used in the process of this invention and in the photovoltaic cells of this invention. Although the wafers can be any shape, wafers are typically circular, square or pseudo-square in shape. By “pseudo-square” is meant a predominantly square shape usually with rounded corners. Thus, in general, the wafers useful in this invention are flat and thin wafers that are typically round, square or pseudo-square in shape. For example, a wafer useful in this invention can be about 50 microns thick to about 400 microns thick. Usually, however, the wafers can be about 100 to about 300 microns thick. If circular they can have a diameter of about 100 to about 200 millimeters, for example 102 to 178 millimeters. If square or pseudo square, they can have a width of about 100 millimeters to about 210 millimeters and where, for the pseudo-square wafers, the rounded corners can have a diameter of about 127 to about 178 millimeters. The wafers useful in the process of this invention, and consequently the photovoltaic cells made by the process of this invention, can have a surface area of about 100 to about 440 square centimeters. The wafers doped with the first dopant that are useful in the process of this invention can have a resistivity of about 0.1 to about 10 ohm·cm, typically of about 0.5 to about 2.0 ohm·cm. The wafers used to manufacture the photovoltaic cells of this invention are preferably made of p-doped, multicrystalline silicon. Although the term wafer as used herein includes the wafers obtained by the methods described, particularly by the sawing or cutting of ingots or blocks of silicon, it is to be understood that the term wafer can also include any other suitable semiconductor substrate useful for preparing photovoltaic cells by the process of this invention.

The front surface of the wafer doped with the first dopant is preferably textured. Texturing generally increases the efficiency of the resulting photovoltaic cell by increasing light absorption. For example, the wafer can be suitably textured using chemical etching, plasma etching or mechanical scribing. The textured wafer is typically subsequently cleaned, for example, by immersion in hydrofluoric acid and then hydrochloric acid with intermediate and final rinsing in de-ionized water, followed by drying. The optional texturing step is preferably done prior to the formation of the emitter layer as described below.

A second dopant of conductivity opposite to the first dopant is applied to the wafer to produce a first layer on the front surface of the wafer having conductivity opposite to the first dopant. Such first layer is the so-called emitter layer. Its formation produces a p-n junction in the wafer. When using a p-doped wafer as in this description of the invention, the front of the wafer is doped with an n-dopant to form the emitter layer. This can be accomplished by depositing a suitable source of n-dopant onto the wafer, and then heating the wafer to “drive” the n-dopant into the surface of the wafer. Gaseous diffusion can be used to deposit the n-dopant onto the wafer surface; however, other methods can also be used, such as ion implantation, solid source diffusion, or other methods used in the art to create an n-doped layer and a p-n junction, preferably proximal to the wafer surface. Phosphorus is a preferred n-dopant, but one or more other suitable n-dopants can be used. For example, one or more of phosphorus, arsenic, or antimony can be used. If, for example, phosphorus is used as the dopant, it can be applied to the wafer using phosphorus oxychloride (POCl₃), or phosphorus containing pastes. For example, liquid POCl₃ can be used. In the process of this invention, one procedure is to add the n-dopant as phosphorus by subjecting the wafers to an atmosphere of phosphorus oxychloride and molecular oxygen at an elevated temperature of about 700° C. to about 850° C. to deposit a layer of a phosphorus glass on the wafer. Such glass layer can be about 5 to about 20 nanometers thick, more typically from about 10 to about 15 nanometers. The n-dopant is preferably applied to—and thus the emitter layer is preferably formed on—only the front surface of the wafer. This can conveniently be accomplished by placing two wafers back-to-back when they are exposed to the material for adding the n-dopant. Other methods for adding the n-dopant to only the front surface of the wafer can, however, be used, such as placing the wafers on a flat surface to shield the back surface of the wafer from being exposed to the dopant material. Other embodiments may allow n-dopant onto all or at least part of the back surface with subsequent compensation by, for example, an aluminium p-dopant introduced during the formation of a back surface field and electrical contact.

In the preferred embodiment of this invention, a surface coating, preferably one that can function as an anti-reflective coating, is deposited on the front surface of the wafer after formation of the emitter layer on the front surface. Such coating can be, for example, a layer of a dielectric such as tantalum oxide, silicon dioxide, titanium oxide, or silicon nitride, which can be added by methods known in the art, for example, plasma enhanced chemical vapor deposition (PECVD), low pressure chemical vapor deposition (LPCVD), thermal oxidation, screen printing of pastes, inks or sol gel, etc. Combinations of coatings can also be used. The preferred coating is an anti-reflective coating comprising silicon nitride. The silicon nitride can be added, for example, by PECVD. Preferably, in the process of this invention, a silicon nitride layer is applied using low pressure chemical vapor deposition (LPCVD). A suitable method for applying the silicon nitride by LPCVD is to expose the wafer to an atmosphere of silicon compound, such as dichlorosilane, and ammonia at an elevated temperature of about 750° C. to about 850° C.

At the time of application, the surface coating deposited on the front surface of the wafer is preferably at least about 70 nanometers thick, and preferably less than about 140 nanometers. The surface coating can be, for example, about 110 to about 130 nanometers thick. The surface coating, preferably silicon nitride, on the finished solar cell can be about 70 to about 100 nanometers thick.

During the step of depositing a surface coating on the front surface of the wafer, the back surface typically also receives a layer of such coating covering all or at least part of the back surface. It is preferable to remove all or most of such coating on the back surface. Any suitable method can be used to remove such surface coating depending on what was used for the surface coating and how it was added. For example, it can be removed by mechanical abrasion or by a chemical etching procedure. In the preferred process of this invention the back surface is plasma etched to remove most or all of any such coating from the back surface of the wafer, preferably without attacking the front surface of the wafer. In one suitable method for plasma etching the back surface of the wafer, the back surface of the wafer is exposed to a gas plasma formed with, for example, a Freon (for example, C₂F₆) and molecular oxygen. The front surface can be protected by, for example, placing two wafers with their front surfaces facing and pressed against each other, or by positioning the wafer with its front surface on a suitable tray or plate, such as a plate of glass or tray with a suitable recess, so that the front surface is protected during the step to remove the coating from the back surface of the wafer.

Grooves are formed in the front surface of the wafer. These are the grooves that will become the front contacts or buried metal contacts after the grooves are metallized or otherwise filled with an electrically conducting material. The grooves are suitably cut or otherwise formed in the front surface of the wafer, all the way through the surface coating, if present, on the front surface. One or more mechanical methods, such as mechanical abrasion, or chemical methods, such as chemical etching, can be used to form the grooves. The grooves are, however, preferably formed by laser scribing. A suitable laser is a Nd:YAG laser or Nd:YVO₄ laser Q-switched at a frequency of about 10 to about 150 kHz. The laser can traverse the wafer surface at a velocity of about 100 to about 10,000 millimeters/second, for example at about 1000 millimeters/second. A first set of grooves are suitably added to the front surface of the wafer in a pattern of parallel lines that can be distributed over the entire front surface of the wafer. The grooves can be about 0.3 to about 2 millimeters apart and can be, preferably, about 10 to about 40 micrometers in width, and about 10 to about 50 micrometers in depth. A second set of grooves is typically added perpendicular to and intersecting the first set of grooves. Such second set of grooves is preferably added as a “bundle” of grooves, or as two or more “bundles” of grooves. This second set of grooves is preferably arranged so that the grooves within each bundle are closely spaced, for example, about 10 to about 50 micrometers apart. There can be about 10 to about 20 grooves in each bundle. Thus, the bundle can be about 0.5 to about 1.5 millimeters wide. The bundles can be about 55 to about 65 millimeters apart from each other on the wafer. After such bundle or bundles of grooves are treated, as described below, to fill them with an electrically conducting material, they can function as bus bars that electrically connect the first set of grooves and can also function as contact points for electrical wires or leads that are attached to the cell. U.S. Pat. No. 4,726,850 to Wenham et al., as mentioned above, discloses methods for making grooves in silicon wafers for buried contacts.

The grooves are typically cleaned and typically etched by one or more chemical etching techniques. For example, the cutting or scribing process generally results in the formation of undesirable silicon debris in and around the grooves. It is desirable to remove such debris, and it is also desirable to further etch the grooves. The grooves can be cleaned and etched by treating the wafer with an aqueous solution of base, such as sodium hydroxide, at a temperature of about 50° C. to about 70° C., and for a time sufficient to eliminate or reduce the silicon debris and to etch the walls of the grooves by a few, for example about 1 to about 10 micrometers. After such cleaning and etching procedure, the wafers can be cleaned by immersing the wafers in hydrofluoric acid and hydrochloric acid, with intermediate and final rinsing in de-ionized water.

The grooves, typically after the preferred cleaning, etching and washing procedures, are preferably doped to add additional second n-dopant to the grooves. As described above for the formation of the emitter layer and p-n junction, the same dopants and doping procedures can be used. Although preferable, it is not necessary for the additional second dopant for the grooves to be the same second dopant used to form the emitter layer. In the preferred process of this invention the grooves are further doped using phosphorus oxychloride. For example, the wafers can be treated in an atmosphere of phosphorus oxychloride and molecular oxygen at a temperature of about 850° C. to about 1000° C. to dope the exposed silicon surfaces in the grooves on the front surface of the wafer. After adding the n-dopant to the grooves, the groove surfaces have, preferably, a sheet resistivity of about 5 to about 15 ohm/square.

In the process of this invention the wafer is treated to form a back surface field (BSF) to increase the efficiency of the photovoltaic cell. A BSF can be formed by generating a p++ layer in the back surface of the wafer. A p++ layer is a layer heavily doped with a p-type dopant. (It is to be understood that if the dopant in the body of the wafer is n-type, the BSF would be formed using an n-type dopant to form a heavily doped n-layer.) Heavily doped means, preferably, that the concentration or level of dopant in the p++ layer or BSF is substantially greater than the concentration or level of p-dopant in the rest of the body of the wafer. For example, the concentration of dopant in a BSF layer in an embodiment of this invention can be about 10 to about 1000, or 10 to about 100 times the concentration of p-dopant present in the body of the silicon wafer. A suitable BSF layer is advantageously formed by alloying or diffusing a substance into the back surface of the silicon wafer. Aluminum is preferably used to form a p++ BSF, but any dopant material can be used which is capable of diffusing into the silicon and resulting in a p++ BSF layer. In a preferred procedure for forming a BSF, a suitable doping composition comprising aluminum, or other dopant material such as, for example, boron, gallium or indium, or a dopant material comprising a combination of one or more thereof, is deposited onto the back surface of the wafer preferably in the form of a conducting paste comprising the dopant material, as well as other components such as an organic solvent, a binder and borosilicate glass. Suitable conducting pastes, such as an aluminum-containing paste, are available commercially from, for example, Ferro Corporation or Du Pont Microcircuit Materials. An aluminum-containing conducting paste is preferred for the process of this invention. The paste is suitably applied to the back surface of the wafer using a screen printing technique by, for example, forcing the conducting paste through a stainless steel mesh screen using a firm rubber squeegee. After such screen printing, the wafers are typically transferred to a furnace, such as an infrared heated, open atmosphere belt conveyor furnace, for paste drying at a temperature of, for example, about 100° C. to about 300° C.

The wafer is thereafter fired at a temperature sufficient to alloy the aluminum or other dopant material, as mentioned above, to the silicon wafer thereby creating a BSF. Preferably, such a temperature is about 700° C. to about 900° C., for example, about 800° C. Such firing or sintering suitably takes place in an atmosphere comprising molecular oxygen, for example, an atmosphere comprising molecular oxygen and nitrogen. Where the doping composition comprises a metal, such as aluminum as the dopant material, the firing also results in a layer of metal, for example aluminum, or a layer comprising a metal, for example aluminum, over the back surface of the wafer. This layer of metal or layer comprising a metal, preferably aluminum, can in the photovoltaic cell of this invention function as a back electrical contact for the cell. Such layer can be about 20 to about 60 microns in thickness.

In a preferred process, bus bar pads are applied to the back surface of the wafer. These bus bar pads are used to solder wires or other electrical leads or conductor to the back of the cell so a number of cells can be electrically interconnected and also connected to the device or system that will utilize the electrical current generated by the cell. Suitable bus bar pads can be conveniently added by applying a commercially available silver-containing conductive paste to the back of the cell by the same screen printing technique as described above for applying the paste of doping composition for the BSF. For example, the silver-containing paste is applied in a pattern of one or more, for example about two to about eight, typically round, square or rectangular shaped areas on the back of the wafer using the screen printing technique. For a square wafer that is about 12.5 centimeters on a side, such areas can be, for example, about 2 to about 8 millimeters in diameter or width. They may be screen printed on the back of the wafer prior to or after screen printing the paste containing the dopant material for the BSF. Preferably, they are added prior to screen printing the paste containing the dopant material used for the BSF. Preferably, the edges of the screen printed areas of the silver-containing paste overlap with the edges of the screen printed layer of paste containing the dopant material for the BSF. When the wafer having the areas of silver-containing paste and the paste containing the dopant material for the BSF are fired to form the BSF, the areas having the silver-containing paste forms the bus bar pads. Suitable silver-containing pastes are commercially availably from, for example, Ferro Corporation or Du Pont Microcircuit Materials, and are formulated similar to the aluminum-containing pastes described above but contain silver rather than aluminum and typically a higher level of glass.

In the preferred process of this invention, after the formation of a BSF, the wafer is treated to apply a first metallic layer to the grooves in the front surface and, preferably, over the bus bar pads. Such first metallic layer can be applied to the entire back surface of the wafer. The first metallic layer preferably comprises nickel but other metals such as silver, tin, copper, gold, or platinum can also be used. Combinations of metals can also be used, such as a combination of two or more of the foregoing. The first metallic layer can also be two or more metal layers. The first metallic layer is preferably deposited by an electrolytic or electroless plating process using commercially available plating solutions. After such deposition of the first metallic layer, the wafer is preferably heated to sinter the deposited metal. In one preferred process of this invention, subsequent to the formation of the BSF, the wafers are immersed in a solution of hydrofluoric acid, rinsed in de-ionized water, and then immersed in commercially available electroless nickel plating solution to deposit a layer of nickel such as, for example, a layer about 0.05 to about 0.2 micrometers, in the groves on the front surface of the wafer and over the entire back surface of the wafer, that is, over the metal layer on the back surface and, if present, over the bus bar pads. After a rinse in de-ionized water and drying, the wafers are heated to a temperature of about 350° C. to about 450° C. for about 5 to about 20 minutes to sinter the nickel. Suitable electroless plating solutions for depositing such a layer of nickel are available from, for example, Cookson Enthone.

In the process of this invention, a mask is applied to the back surface of the wafer. The mask is applied over the metal layer, for example, the aluminum layer, produced during the formation of the BSF and, if present, over the first metallic layer, for example, the layer of sintered nickel. The mask is preferably made of a material that can be easily applied by one or more techniques such as spraying, screen printing, painting, chemical vapor deposition or other method as appropriate for the material. After the mask material is applied, it is typically treated by a subsequent developing, curing, setting or other fixation method, as appropriate.

The mask material is preferably selected so it is resistant to thermal exposure and electrolytic or electroless metal plating solutions. The mask material can be, for example, a lacquer, an elastomer, a resist material such as those used in the semiconductor industries, a wax, a polymeric material, and the like. Combinations of such materials can be used. Suitable materials for the mask can be obtained from, for example, Coates Circuit Products Ltd. such as the XZ34 or XZ35 materials, or from Shipley Ronal, such as a Dynalith ER400 material.

In the preferred embodiment, the mask is screen printed onto the back surface over the entire back surface except for the areas over the bus bar pads, if present. The mask is typically dried in open atmosphere at ambient temperature, and, preferably, is not removed after completion of the solar cell fabrication process.

In order to complete the formation of the front, buried contacts, they are filled with an electrically conductive material. The conductive material is preferably one or more highly conductive metals such as silver, nickel, tin, copper, gold, platinum or other highly conductive metal. The grooves can be filled with such metal by one or more techniques known to those of skill in the art such as by filling the grooves with a paste containing a metal by, for example, using a squeegee to press or force the paste into the grooves, and thereafter heating the wafer to an elevated temperature and for a time to convert the paste into a metal conductor. Preferably, however, the metal is added to the grooves by one or more electroplating techniques known to those of skill in the art such as, for example, electrolytic or electroless plating. In one preferred process of this invention for filling the grooves with a conducting metal, the grooved wafers, preferably having the layer of sintered nickel deposited from the previous step as described above, are treated to apply a layer of copper to the nickel, and then a layer of silver to the copper. The layer of copper can be about 2 to about 10 micrometers in thickness. In one such treatment, the wafer is immersed in commercially available electroless copper solution, then rinsed in water, then immersed in an electroless silver plating solution and then rinsed in water and dried. Such procedure applies a conductive copper layer and a silver layer to the grooves and to any part of the back surface that is not protected by the mask, such as the part over the bus bar pads. The part of the back surface not protected by the mask is preferably limited to the regions where, if present, bus bar pads are located.

It is not, however, necessary to apply the conductive metal such as copper, silver or a combination thereof, to the grooves on the front surface of the wafer and to the back surface of the wafer at the same time. It is, however, convenient and preferable to use the above-described electroless method for applying the conductive metals to both the front grooves and back bus bar pads at the same time using the same process steps and chemical solutions. Methods for filling the grooves with a conductive metal are also disclosed in European Patent Application Publication Number 1182709, Jensen et al., published on Feb. 27, 2002, which is incorporated herein by reference in its entirety.

If desired, photovoltaic cells made by the process just described can be edge isolated by, for example, laser scribing around the front or back surface at or very near the edge of the cell and then, preferably, physically breaking off the edge of the cell to electrically separate the front and back sides of the cell from each other. Other methods for edge isolation can also be used such as mechanically grinding, cutting off the edge of the cell or plasma etching.

After the plating steps to form the front contacts, for example, after an edge isolation step, the mask can be removed, if necessary or otherwise desired, by methods such as solvent dipping, gaseous etching, mechanical lifting or other as appropriate. In the preferred embodiment of this process the mask is not removed, and electrical cell interconnection allowed by the use of unmasked silver bus bar solder pads.

In a process used prior to this invention, after the firing or sintering of the dopant material to form the BSF, the excess doping material on the back surface of the wafer, for example aluminum, is removed using hydrochloric acid. This results in the formation of a large amount of waste material containing spent hydrochloric acid and aluminum. In the process of this invention, such step of removing the aluminum or other dopant material can be used to a lesser extent and, preferably, is eliminated. In the process of this invention, after the step of adding the dopant material, such as aluminum, for the formation of the BSF, and optionally one or more layers of a conducting metal, such as nickel, to the back surface, a mask is applied as described above which protects the metal layer on the back of the wafer from being attacked by the plating solutions. Thus, in the preferred processing sequence of this invention, the doping composition used to form the BSF is applied to the back surface of the wafer, preferably using a screen printing technique, the wafer is heated to form a BSF and a metal layer of the dopant material in the doping composition, a layer of nickel is deposited on the back surface over the metal layer and in the grooves on the front surface, the nickel layer is sintered, and then a mask is applied to at least a portion and preferably all of the back surface of the wafer over the metal layer or, if present, the sintered nickel layer (but preferably not over any bus bar pads, if present). In the preferred process of this invention, the excess dopant material after the wafer is treated to form the BSF is not treated, such as by a hydrochloric acid etch, to remove any of the excess dopant material. By not performing the etching step to remove the excess dopant material, the process of this invention can be used to eliminate the formation of the spent hydrochloric acid containing aluminum or other dopant material and to save the cost of plating a metal or metals such as, for example, copper and silver onto the back of the cell.

The photovoltaic cells of this invention have high efficiency in converting light energy into electrical energy. Photovoltaic cells of this invention made using a multicrystalline silicon wafer, preferably of an area of about 100 to about 200 square centimeters, can have an efficiency of at least about 16.2% percent, and can have efficiency of up to or of at least about 16.9% percent. As used herein, the efficiency of the solar cells made by the process of this invention is measured using the standard test conditions of AM1.5G at 25° C. using 1000 W/m² (1000 watts per square meter) illumination where the efficiency is the electrical energy output of the cell over the light energy input, expressed as a percent. Photovoltaic cells of this invention made using a multicrystalline silicon wafer of area typically about 150 square centimeters have been demonstrated to have an efficiency of at least 15.5%, for example 16.2% and 16.9%.

The photovoltaic cells of this invention can be used to form modules where, for example, a plurality of such cells are electrically connected in a desired arrangement and mounted on or between a suitable supporting substrate such as a section of glass or other suitable material. Methods for making modules from solar cells are well known to those of skill in the art.

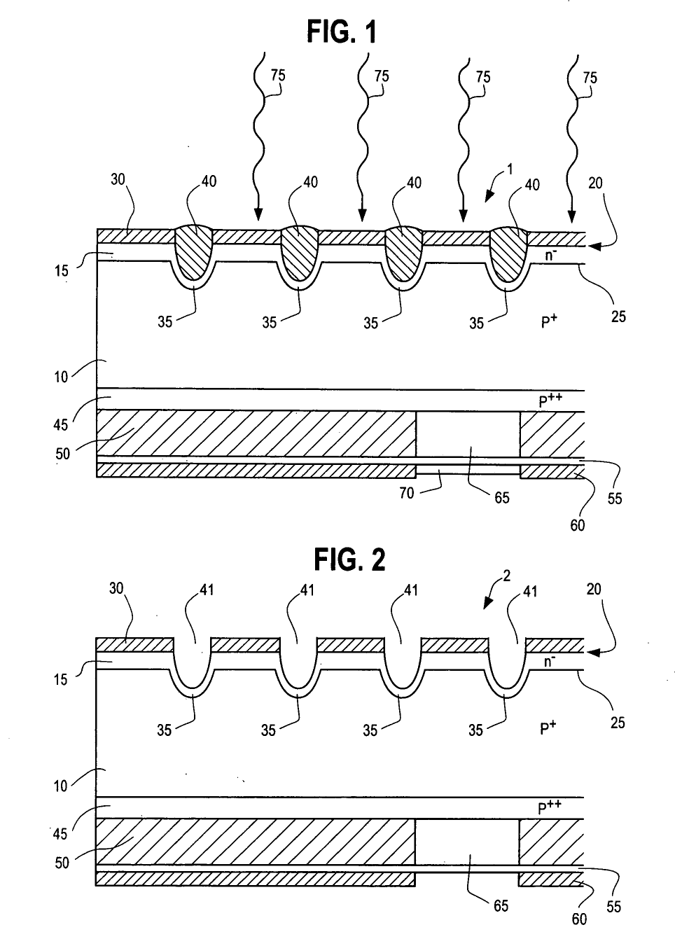

FIG. 1 shows a cross-section of a part of photovoltaic cell 1 made in accordance with an embodiment of the process of this invention. The photovoltaic cell 1 of FIG. 1 has a boron, p-doped, multicrystalline wafer 10. An n-doped layer 15, formed by phosphorus diffusion, is present next to the front surface 20 of silicon wafer 10. A p-n junction 25 is present where the boron doped substrate 10 meets the n-doped layer 15. Silicon nitride coating 30 has been applied over the n-doped layer 15. Heavily doped n-layer 35 is under each buried metal contact 40. The BSF 45 is within the silicon wafer 10 and adjacent to aluminum metal layer 50. In this embodiment, aluminum layer 50 was formed during the step to form the BSF where an aluminum-containing paste was applied to the back surface of the wafer and the wafer was heated at an elevated temperature to form the BSF and the aluminum metal layer 50. The aluminum layer 50 serves as the back electrical contact of the cell. Layer 55 is a layer of nickel which can be deposited by electroless deposition followed by sintering at an elevated temperature. Layer 60 is a polymeric mask applied to the wafer after the deposition of nickel layer 55. One bus bar pad 65 is shown in electrical contact with the aluminum layer 50. Bus bar pad 65 also has a layer 70 of copper and silver. Incident light 75 is shown impinging on cell 1.

FIG. 2 shows the cross-section of a partially-processed boron, p-doped, masked, multicrystalline wafer 2 made in accordance with an embodiment of this invention. Items numbered in FIG. 2 are the same as shown in FIG. 1. In FIG. 2 the grooves 41 in the front surface of the wafer, are not filled with conducting metal as shown in FIG. 1. Also, in FIG. 2, the bus bar pad 65 does not have an outer layer of copper and silver. FIG. 2 shows how the mask layer 60 is positioned over metal layer 50 and 55 except for the location over the bus bar pad 65. Although not shown in the Figures, the mask layer 60 can be directly on metal layer 50.

### EXAMPLES OF THE INVENTION

Photovoltaic cells of this invention are prepared using the general process as follows:

1. Starting Material
The silicon wafers used are multicrystalline wafers, cut from blocks or bricks of cast multicrystalline silicon doped p-type with boron. The wafer dimensions are 12.5 centimeter (per side) squares. The wafer thickness is 250 micrometers.

2. Wafer Surface Preparation
The wafers are “texture” etched by treating them with a chilled solution of hydrofluoric acid and nitric acid followed by rinsing in de-ionized water and by drying.

3. Phosphorus Doping
Wafers are placed in pairs (touching) in slots in a quartz wafer carrier and treated in an atmosphere of POCl₃ vapor and oxygen at a temperature of 780° C. to form the emitter layer.

4. Silicon Nitride Deposition
The wafers are treated in an atmosphere of silicon nitride and ammonia gases to deposit an 80 nanometer thick film of silicon nitride on the front surface of the silicon wafer.

5. Laser Grooving
A number of grooves are cut into the front surface (the surface with the silicon nitride film) that subsequently form the conductive grid by which the electrical current is carried. Each groove has dimensions of typically 20 micrometers in width and 40 micrometers in depth and is formed by laser ablation of the surface material using a Nd:YAG laser. The groove pattern is a first group of parallel lines 2 millimeters apart distributed over the entire wafer surface, and a second group of grooves perpendicular to the first group and arranged in two bundles with a distance of about 6 centimeters between each bundle. Each bundle has parallel grooves within a bundle width of 2 millimeters.

6. Groove Cleaning
The action of laser grooving generally results in silicon debris on the wafer surface and groove sidewalls that contain undesirable crystal imperfections. Accordingly, the wafers are etched in a solution of sodium hydroxide to dissolve the silicon debris and etch the groove walls to a depth of a few microns. The wafers are then cleaned by subsequent immersions in acid with intermediate and final rinsing in de-ionized water followed by drying.

7. Groove Doping
The silicon wafers are placed in a quartz wafer carrier, inserted into a quartz tube and treated in an atmosphere of POCl₃ vapor and molecular oxygen with a subsequent drive-in step to dope phosphorus into the exposed silicon surface to a sheet resistivity of about 8 ohm/square.

8. Plasma Etch
The silicon nitride layer on the back surface of the wafer is removed by etching in a gas plasma formed with Freon and oxygen. This is achieved by placing the wafers with their front surfaces touching each other and exposing the back surfaces to the gas plasma or by placing the wafers with the front side facing down on a glass plate.

9. Aluminum Paste Deposition and Silver Contact Pads
Using a high speed, dual stage printer, a silver-containing, hot wax paste is screen printed on the back surface of the wafer in a pattern of small areas that will later form silver bus bar pads after the paste is fired at elevated temperatures. Such paste dries instantly after application. The printer then screen prints an aluminum-containing paste over the remaining portions of the back surface of the wafer.

10. Aluminum and Silver paste Sintering
The screen printed silicon wafers are placed on the belt of an open atmosphere infra-red furnace and conveyed through a drying zone where the organic solvents in the pastes and binders are removed at temperatures around 200° C., then through a firing zone where the metal and glass components of the conductive pastes are fused together and into the surface of the silicon wafer forming a BSF and a layer of aluminum and silver bus bar pads on the back surface of the wafer.

11. Nickel Plating
The wafers are immersed in a solution of hydrofluoric acid and rinsed in de-ionized water. The wafers are then immersed in a commercially available alkaline electroless nickel plating solution to deposit 0.1 micrometer nickel film followed by a rinse in de-ionized water before drying.

12. Nickel Sintering
The nickel-plated wafers are heated to a temperature of 400° C. in a nitrogen atmosphere to sinter the nickel into the silicon surface.

13. Masking
A polymer mask material, such as Dynalith ER 400 from Shipley Ronal, or ZX34 or ZX35 from Coates Circuit Products Ltd. is printed onto the back contact in the desired pattern, typically covering the entire back surface except for the silver bus bar pads, although slightly overlapping these pads so as to protect the aluminum layer from attack by the subsequent plating solutions. The mask is typically dried at low temperature in an infra-red belt conveyor furnace.

14. Copper and Silver Electroless Plating
Wafers are treated using the following procedure to apply a 5 micron thick film of copper in the grooves and on to the exposed (i.e., areas without mask) back surface of the wafer. Immersion in nitric acid followed by a rinse in water, immersion in hydrofluoric acid, rinse in water, immersion in an acid electroless nickel solution, second rinse in water, immersion in electroless copper solution, rinse in water, immersion in an electroless silver solution, and a rinse in water followed by drying.

15. Edge Isolation
The edges of the wafer are removed by cutting a groove to a depth of 100-150 micrometers into the silicon surface on the back of the wafer and around the perimeter at a distance of 1 millimeter from the wafer edge. Cleaving and discarding the 1 millimeter silicon at the edge removes the edge material.

Example 1 in Table 1 below shows the results of the testing of photovoltaic cells made using a mask over the BSF and metal layer on the back surface of the wafer prior to plating copper in the front grooves.

TABLE 1

| | | Area | Jsc | Voc | FF | Efficiency |
|---|---|---|---|---|---|---|
| | Material | [cm²] | [mA/cm²] | [mV] | [%] | [%] |
| Example 1 | Multi-cryst | 156 | 34.5 | 613 | 78 | 16.2 |
| | Wafer | | | | | |

Jsc = short circuit current of cell per square centimeter under 1000 W/m² illumination with AM1.5G spectrum
Voc = open circuit voltage of cell under 1000 W/m² illumination with AM1.5G spectrum
Efficiency = electrical energy output over light energy input measured under 1000 W/m² illumination using AM1.5G at 25° C.
FF = Fill Factor, a measure of power out/(Isc*Voc)

U.S. Provisional Patent Application No. 60/547,123, filed on Feb. 24, 2004, is incorporated herein by reference in its entirety.

Only certain embodiments of the invention have been set forth and alternative embodiments and various modifications will be apparent from the above description to those of skill in the art. These and other alternatives are considered equivalents and within the spirit and scope of the invention.

1. A process for making a photovoltaic cell using a semiconductor wafer doped with a first dopant, the wafer having a front surface and a back surface, the process comprising the steps of (a) forming a first layer on the front surface of the wafer, the first layer comprising a second dopant of a conductivity type opposite the first dopant; (b) forming grooves in the front surface; (c) adding a second dopant to the grooves; (d) depositing dopant material on the back surface of the wafer; (e) treating the wafer having the dopant material deposited thereon to form a back surface field (BSF); (f) applying a mask to at least a portion of the back surface of the wafer after the treating; and (g) adding a conductive material to the grooves to form an electrical contact.

2. The process of claim 1 further comprising depositing a surface coating on the front surface over the first layer.

3. The process of claim 2 wherein the grooves are formed after depositing the surface coating.

4. The process of claim 1 wherein the treating forms a layer comprising a metal at the same time as the back surface field.

5. The process of claim 4 wherein the dopant material for the back surface is deposited using a paste comprising aluminum and the layer comprising a metal comprising aluminum.

6. The process of claim 5 wherein the dopant material for the back surface is screen printed on the back surface of the wafer.

7. The process of claim 1 wherein the semiconductor wafer is a multicrystalline silicon wafer.

8. The process of claim 1 wherein the mask comprises a polymeric material.

9. A process for making a photovoltaic cell from a silicon wafer having a front surface and a back contact layer comprising a metal on a back surface, the process comprising applying a mask to at least a portion of the back contact layer.

10. The process of claim 9 wherein the silicon wafer has grooves in the front surface and the process further comprises adding one or more metal conductors to the grooves in a step after applying the mask, the mask being applied to protect the back contact layer from attack by materials used to add the metal conductor to the grooves, and to reduce the amount of materials used to add the metal conductors to the grooves.

11. A photovoltaic cell comprising a doped silicon wafer having a front surface and a back surface, a p-n junction proximate to the front surface, a plurality of grooves in the front surface having a conducting metal, a back surface field, a layer comprising a metal over the back surface field and a mask over at least a portion of the back layer comprising a metal.

12. The photovoltaic cell of claim 11 wherein the silicon wafer comprises multicrystalline silicon.

13. The photovoltaic cell of claim 11 further comprising a textured front surface.

14. The photovoltaic cell of claim 11 further comprising an antireflective coating on the front surface.

15. A wafer for the manufacture of a photovoltaic cell comprising a semiconductor material and a front and back surface, the wafer comprising a layer on the back surface comprising a metal and a mask over at least a portion of the layer comprising a metal.

16. The wafer of claim 15 comprising multicrystalline silicon.

17. The wafer of claim 16 wherein the layer comprising a metal comprises aluminum and the mask comprises a polymeric material.

18. Modules comprising photovoltaic cells of claim 11.

19. The process of claim 1 wherein the steps are performed in the order (a), (b), (c), (d), (e), (f), (g).
